(19) United States
(12) Patent Application Publication
(10) Pub. No.: US 2011/0304897 A1
(43) Pub. Date: Dec. 15, 2011

(54) Optical Semiconductor Module and Method for Assembling the Same

(75) Inventors: Kazuo Kasaya, Kanagawa-ken (JP); Ken Tsuzuki, Kanagawa-ken (JP); Toshiki Nishizawa, Kanagawa-ken (JP); Hiroshi Tomita, Kanagawa-ken (JP); Yuji Mitsuhashi, Kanagawa-ken (JP)

(73) Assignees: NTT Electronics Corporation, Yokohama-shi, Kanagawa (JP); Nippon Telegraph and Telephone Corporation, Tokyo (JP)

(21) Appl. No.: 13/123,216

(22) PCT Filed: Oct. 9, 2009
(86) PCT No.: PCT/JP2009/005301

§ 371 Date: Aug. 25, 2011

(30) Foreign Application Priority Data
Oct. 9, 2008 (JP) 2008-262381

(51) Int. Cl. G02F 1/00; H01L 21/50; G02B 27/30

(52) U.S. Cl. 359/237; 359/641; 29/25.01

(57) ABSTRACT

An optical semiconductor module in which displacement resulting from fixation of lenses is effectively corrected includes a first lens (102), a second lens (103), and a third lens (104) arranged between a semiconductor laser (101) and a semiconductor optical modulator (105). The first lens (102) and the second lens (103) form a collimate lens optical system. The first lens (102) converts light emitted by the semiconductor laser (101) into parallel light rays. The second lens (103) focuses the parallel light rays on the semiconductor optical modulator (105) to couple the light rays to the semiconductor optical modulator (105). The third lens (104) has a longer focal distance than the first and second lenses. Thus, displacement of the lenses resulting from fixation thereof can be corrected by adjusting in position and fixing the first and second lenses (102, 103) and then adjusting in position and fixing the third lens.

### TECHNICAL FIELD

The present invention relates to an optical semiconductor module and a method for assembling the optical semiconductor module. The optical semiconductor module is configured to be able to effectively correct displacement of lenses resulting from fixation thereof.

### BACKGROUND ART

In an optical semiconductor module containing a plurality of optical semiconductor devices, a plurality of optical elements are optically coupled together via lenses. The optical elements need to be coupled together at a high efficiency. Furthermore, there has been a demand for miniaturization of the optical semiconductor module. Thus, when two optical semiconductor devices are optically coupled together via lenses, two lenses with almost the same focal distance are used to achieve a high optical coupling efficiency. The reason for the use of such lenses is as follows. The field diameter of light in the optical semiconductor element, that is, the full width at half maximum of power distribution of light propagating through the optical semiconductor element, is the same, that is, about 2 μm in any types of elements. Thus, the optical coupling between optical semiconductor devices can be achieved with a reduced optical coupling loss by using two lenses with almost the same focal distance to set an image magnification to almost 1.

However, when two lenses with almost the same focal distance are used to optically couple two optical semiconductor devices, optical coupling loss is increased even by slight axial displacement of the lenses. If for example, an adhesive such as an epoxy adhesive is used to fix the lenses or optical components for correction of the optical axis, the lens positions cannot be kept stable for a long time. Thus, an optical coupling efficiency may vary greatly over time, leading to a reduced output light intensity. Furthermore, when fixation means based on YAG laser welding is used to fix the lenses or the optical components for correction of the optical axis, stability can be maintained for a long time, but axial displacement resulting from welding disadvantageously reduces the optical coupling efficiency and thus the output light intensity.

For solution of such a problem, an optical semiconductor module with a first lens and a second lens which have different focal distances is important. This is because the optical semiconductor module serves to suppress a decrease in optical coupling efficiency resulting from the axial displacement of the lenses, thus allowing the optical coupling efficiency to be stabilized (see Patent Literature 1: Japanese Patent Laid-Open No. 2007-115933).

The optical semiconductor module illustrated in Patent Literature 1 uses two lenses with different focal distances to increase the image magnification of light coupled to optical semiconductor devices. A decrease in optical coupling efficiency as a result of axial displacement of lenses occurring in a direction orthogonal to the optical axis is smaller when one of two lenses with different focal distances which has a longer focal distance is fixed than when lenses with substantially the same focal distance are used. Thus, the use of the means described in Patent Literature 1 allows provision of an optical semiconductor module configured to suppress a decrease in output light intensity to stabilize the optical coupling efficiency when the lenses are axially displaced as a result of fixation thereof.

### CITATION LIST

### Patent Literature

Patent Literature 1: Japanese Patent Laid-Open No. 2007-115933

### SUMMARY OF THE INVENTION

### Technical Problem

However, even the use of two lenses with different focal distances fails to sufficiently correct displacement of the lenses resulting from fixation thereof.

Furthermore, for application to new standards for miniaturized optical transceivers (SFF, size: 71 mm×51 mm) which replace conventional standards (LFF, size: 101.6 mm×88.9 mm), there has been a demand for a reduction in the size of the optical semiconductor module. In this case, an increase in the number of components of the optical semiconductor module hinders the miniaturization of the optical semiconductor module.

### Solution to Problem

A configuration of an optical semiconductor module according to the present invention which solves the above-described problems is as follows. The optical semiconductor module comprises a first optical element, a first lens configured to convert light emitted by the first optical element into parallel light rays, a second lens configured to focus the parallel light rays, a third lens arranged between the first lens and the second lens, and a second optical element positioned such that the light is focused on the second optical element by the second lens, the first optical element, the first lens, the second lens, the third lens, and the second optical element being built into the optical semiconductor module, and is characterized in that the third lens has a longer focal length than each of the first lens and the second lens.

Furthermore, the configuration of the semiconductor module according to the present invention is characterized in that when the first lens and the second lens have an equal focal distance, the focal distance of the third lens is at least 20 times as long as the focal distance of the first and second lenses and at most 300 mm, and when the first lens and the second lens have different focal distances, the focal distance of the third lens is at least 20 times as long as a longer one of the focal distances of the first and second lenses and at most 300 mm.

Furthermore, the configuration of the semiconductor module according to the present invention is characterized in that the first lens, the second lens, and the third lens are housed in a metal housing and fixed, by YAG laser welding, on a carrier with the first optical semiconductor element and the second optical semiconductor element mounted thereon.

Furthermore, the configuration of the semiconductor module according to the present invention is characterized in that an isolator is provided between the first lens and the third lens.

Furthermore, the configuration of the semiconductor module according to the present invention is characterized in that the first optical element is a light source, and the second optical element is an optical modulator.

Furthermore, the configuration of the semiconductor module according to the present invention is characterized in that the first optical element is a wavelength tunable laser, and the semiconductor module comprises a wavelength locker at a position on which light output by the second optical element is incident.

A configuration of a method for assembling a semiconductor module according to the present invention is characterized by comprising fixing a first optical element and a second optical element on a carrier, then adjusting a first lens, a second lens, and a third lens in position so that light focused by the second lens couples to the second optical element, and fixing the first lens and the second lens to the carrier by YAG laser welding, and then fixing the third lens with a long focal distance to the carrier.

Furthermore, a configuration of a semiconductor module according to the present invention comprises an optical element, a carrier with a lens mounted thereon, and a Peltier cooler with the carrier mounted thereon, the optical element, the carrier, and the Peltier cooler being all provided in a package, as well as a lead frame exposed from the package in order allow an electric signal to be input and output, and is characterized in that a part of a side wall of the package is ceramic, electric wiring for allowing the Peltier cooler to be controlled is arranged under the carrier, and the electric wiring is further arranged through a hole inside the ceramic so as to connect to the lead frame.

Furthermore, the configuration of a semiconductor module according to the present invention is characterized in that the electric wiring for allowing the Peltier cooler to be controlled is connected to a metal layer arranged in a part of an inner wall surface of the ceramic, and the electric wiring is further arranged though an inside of the ceramic so as to connect to the lead frame.

### Advantageous Effects of the Invention

The use of the means according to the present invention enables provision of an optical semiconductor module configured to suppress a decrease in output light intensity to stabilize the optical coupling efficiency when the lenses are axially displaced as a result of fixation thereof.

### BRIEF DESCRIPTION OF DRAWINGS

FIG. 1 is a diagram showing an optical semiconductor module according to Embodiment 1 of the present invention;

FIG. 2 is a characteristic diagram illustrating the relationship between a optical coupling loss and the position displacement of a first lens and a second lens;

FIG. 3 is a characteristic diagram illustrating the relationship between the position displacement of a third lens and the optical coupling loss;

FIG. 4A is a characteristic diagram illustrating a variation in optical coupling loss with respect to the position displacement of the third lens resulting from fixation thereof;

FIG. 4B is a characteristic diagram illustrating the dependence of the focal distance of the third lens on the optical coupling loss;

FIG. 5 is a diagram showing an optical semiconductor module according to Embodiment 2 of the present invention;

FIG. 6 is a characteristic diagram illustrating the dependence of the focal distance of the third lens on the optical coupling loss;

FIG. 7 is a diagram showing an optical semiconductor module according to Embodiment 3 of the present invention;

FIG. 8A is a diagram showing a conventional example of wiring for allowing a Peltier cooler to be controlled;

FIG. 8B is a diagram showing the present embodiment of wiring for allowing a Peltier cooler to be controlled;

FIG. 9 is a diagram showing an optical semiconductor module according to Embodiment 4 of the present invention;

FIG. 10 is a characteristic diagram illustrating an output from an optical fiber according to Embodiment 4;

FIG. 11 is a characteristic diagram illustrating an extinction characteristic of an optical modulator;

FIG. 12A is a characteristic diagram showing an eye pattern;

FIG. 12B is a characteristic diagram showing an eye pattern;

FIG. 12C is a characteristic diagram showing an eye pattern;

FIG. 12D is a characteristic diagram showing an eye pattern; and

FIG. 13 is a characteristic diagram illustrating BER (Bit error rate) characteristic.

### DESCRIPTION OF EMBODIMENTS

An optical semiconductor module and a method for assembling the optical semiconductor module will be illustrated below. In the present embodiment, two optical semiconductor devices are mounted in one optical semiconductor module. The two optical semiconductor devices are optically coupled together using three lenses. Here, the three lenses include a first lens, a second lens, and a third lens. The third lens is arranged between the first lens and the second lens and has a longer focal distance than the first and second lenses.

Furthermore, when the optical semiconductor module is assembled, first, the two optical semiconductor devices are fixed on the carrier. Then, the positions of the first lens, the second lens, and the third lens are then adjusted, and the first lens and the second lens are fixed. Then, the third lens with the longer focal distance is fixed.

### Embodiments

### Embodiment 1

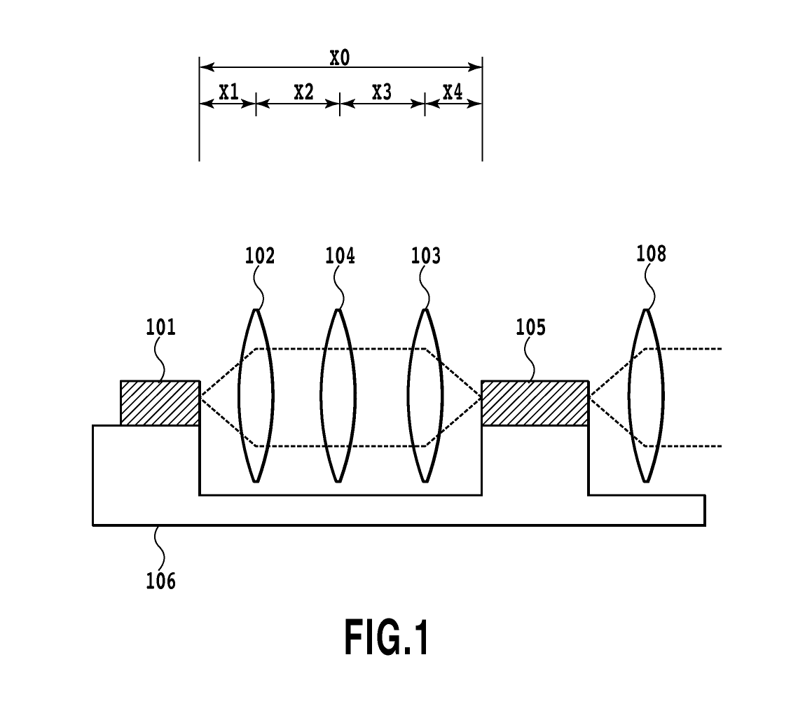

FIG. 1 shows Embodiment 1 of the present invention. As shown in FIG. 1, an optical semiconductor module according to the present embodiment includes, as optical semiconductor devices mounted on a carrier 106, a semiconductor laser 101 and a semiconductor optical modulator 105 both of which are waveguide-type optical semiconductor devices. The optical semiconductor module further includes a first lens 102, a second lens 103, and a third lens 104 all of which are adjusted in position such that light emitted by the semiconductor laser 101 couples to the semiconductor optical modulator 105 with a reduced optical coupling loss.

The semiconductor laser 101 used herein is a Fabry-Perot laser with a 1.55-μm oscillation wavelength band. The semiconductor optical modulator 105 used herein is an electrolyte absorption (EA) modulator configured to be able to deal with the 1.55-μm band.

When the optical semiconductor module according to the present embodiment is assembled, first, the two optical semiconductor devices, the semiconductor laser 101 and the semiconductor optical modulator 105, are fixed on the carrier 106. Then, the first, second, and third lenses 102, 103, and 104 are adjusted in position on the carrier 106. The first lens 102 and the second lens 103 are fixed on the carrier 106 with an epoxy adhesive. Finally, the third lens 104 with a long focal distance is adjusted in position again and fixed on the carrier 106 with an epoxy adhesive.

As described above, the third lens 104, adjusted in position again and fixed after the fixation of the first lens 102 and the second lens 103, has the long focal distance. Thus, position displacement of the first lens 102 and the second lens 103 resulting from fixation thereof can be effectively corrected.

The following method is also possible. The initial lens position adjustment involves only the first and second lenses 102 and 103. After the first lens 102 and the second lens 103 are fixed, the third lens 104 with the long focal distance is inserted, adjusted in position, and then fixed. However, in this case, since the initial lens position adjustment does not involve the third lens 104, the displacement of the optical axis increases by an amount corresponding to the refractive index of the third lens 104. Thus, much time and effort is required to adjust in position and fix the third lens 104 after the fixation of the first and second lenses 102 and 103.

The lens 102 is arranged at a distance x1 from the exit end of the semiconductor laser 101. The lens 104 is arranged at a distance x2 from the lens 102. The lens 103 is arranged at a distance x3 from the lens 104. The incident end of the semiconductor optical modulator 105 is arranged at a distance x4 from the lens 103. Here, x1 is 0.75 mm, x2 is 5 mm, x3 is 2 mm, and x4 is 0.75 mm. Both the lenses 102 and 103 have a focal distance of 0.75 mm. The lens 104 has a focal distance of 75 mm.

The first lens 102 converts light emitted by the semiconductor laser 101 into parallel light rays. The parallel light rays pass through the third lens 104, and the second lens 103 focuses the parallel light rays on the semiconductor optical modulator 105 to couple the light rays to the semiconductor optical modulator 105. The lenses 102, 103, and 104 are adjusted in position and then fixed on the carrier 106.

Here, the optical coupling loss is temporarily set to zero during position adjustment. However, during the subsequent fixation of the lenses 102 and 103, an optical coupling loss may occur if the lenses are displaced in position by about 2 μm. The lenses are normally displaced in position by about 2 μm when the lenses are fixed with an epoxy adhesive.

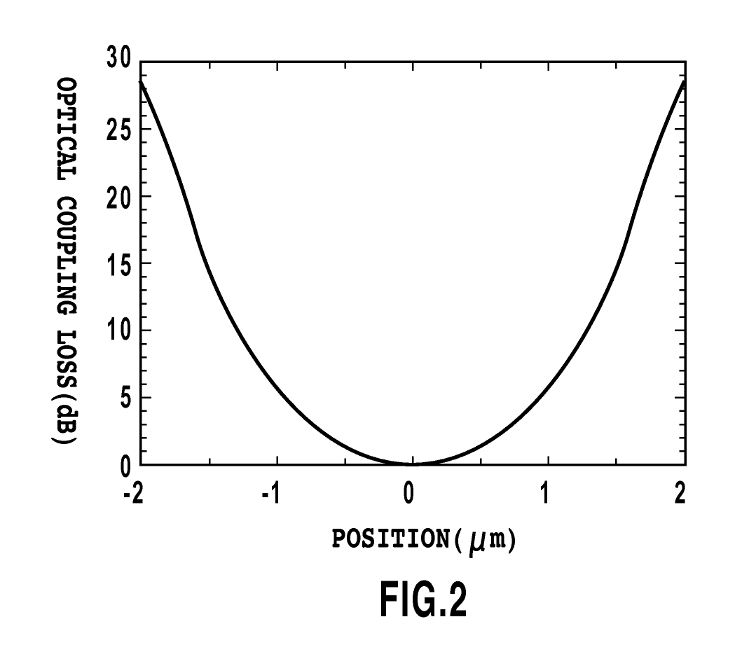

FIG. 2 illustrates the results of calculation of the tolerance of a coupling system with the third lens 104 omitted; the coupling system includes only the lenses 102 and 103. The axis of abscissas indicates the position (displacement) of the fixed lens. The axis of ordinate indicates the optical coupling loss. The optical coupling loss is about 5 dB when the position displacement of the lens is 1 μm, and is about 28 dB when the position displacement of the lens is 2 μm. When the coupling system is formed only of the lenses 102 and 103, a position displacement of 1 to 2 μm results in a heavy optical coupling loss.

In the present invention, the third lens 104 arranged between the lenses 102 and 103 is adjusted in position and then fixed. At this time, the lens 104 is used to correct the optical axis of the optical system formed of the lenses 102 and 103. Here, the lens 104 used has a longer focal distance than the lenses 102 and 103. When the lens 104 with the long focal distance is thus interposed into a collimate lens coupling system with a short focal distance, mounting tolerance can be increased.

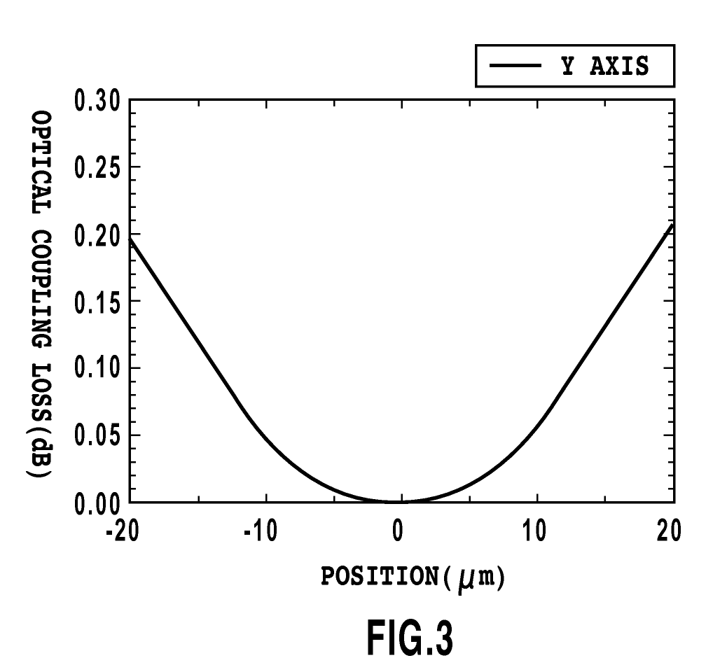

FIG. 3 shows the results of calculation of the tolerance for the fixture of the lens 104 in which the lens 104 is arranged in the coupling system of the lenses 102 and 103. The axis of abscissas indicates the position (displacement) of the fixed lens. The axis of ordinate indicates the optical coupling loss. The optical coupling loss is 0.05 dB when the position displacement of the lens 104 is 10 μm, and is about 0.20 dB even when the position displacement of the lens 104 is 20 μm. Thus, even when the lens 104 is displaced in position by an amount 10 times as large as that in the case of the lenses 102 and 103, the resultant optical coupling loss is only about 1/20 of that in the case of the lenses 102 and 103.

As described above, the effect, on the optical coupling loss, of the position displacement of the lens 104 resulting from fixation thereof is at most 1/100 of that in the case of the lenses 102 and 103. This indicates that the optical coupling loss can be reduced by adjusting in position and fixing the lens 104 after the fixation of the lenses 102 and 103, allowing an optical semiconductor module with a high coupling efficiency to be produced.

Light emitted by the semiconductor optical modulator 105 is converted into parallel light rays by a fourth lens 108. The light rays are then focused by a fifth lens (not shown in the drawings). The resultant light is connected to an optical fiber (not shown in the drawings).

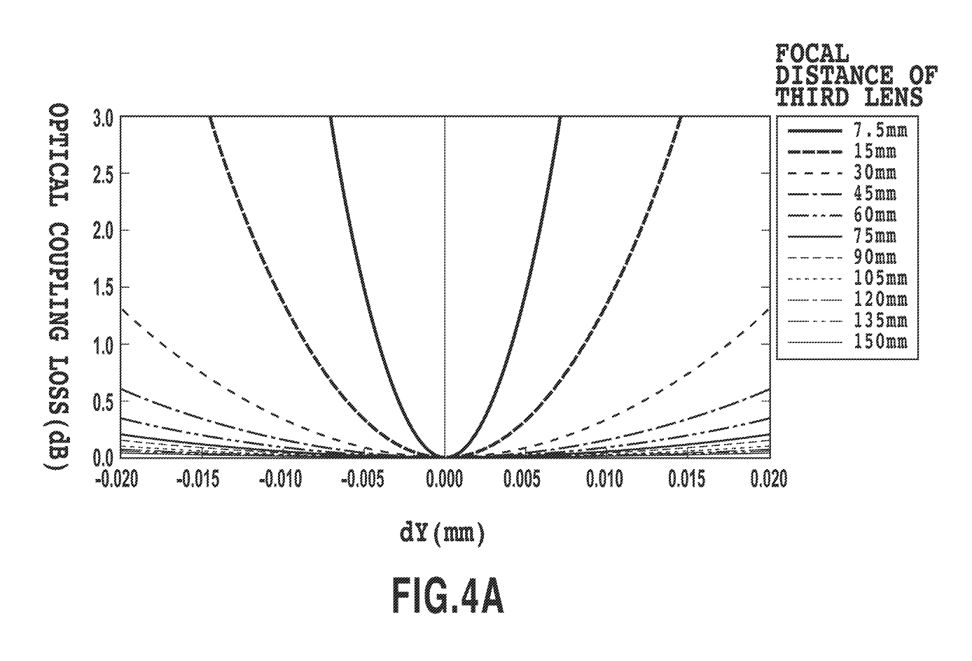

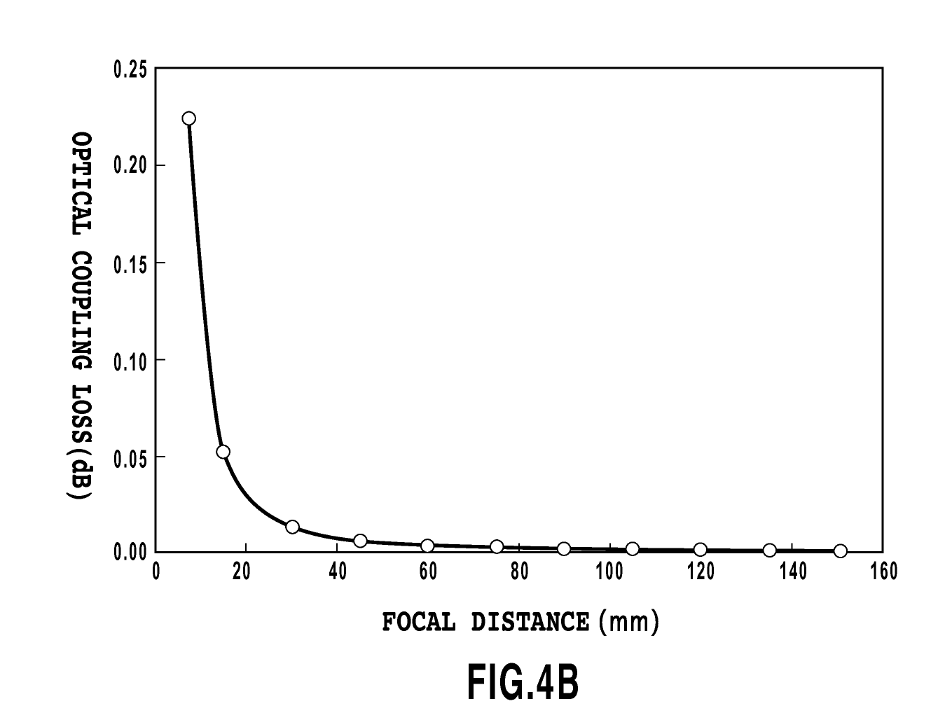

FIG. 4 illustrates a variation in optical coupling loss in association with the focal distance of the third lens 104. FIG. 4A illustrates a variation in optical coupling loss with respect to the displacement of the third lens 104 resulting from fixation thereof when the focal distance of the third lens 104 ranges from 7.5 mm to 150 mm. FIG. 4 indicates that when the focal distance of the third lens varies from 7.5 mm to 150 mm, an increase in optical coupling loss with respect to the displacement of the lens 104 resulting from fixation thereof decreases by at least one order of magnitude.

FIG. 4B illustrates the dependence of the focal distance of the lens 104 on the optical coupling loss resulting from the position displacement of the lens 104 when the lenses 102 and 103 have a focal distance of 0.75 mm. The position displacement of the lens 104 is 2 μm. When the focal distance of the third lens 104 varies from 7.5 mm to 15 mm, the optical coupling loss decreases sharply from about 0.22 dB to 0.05 dB. Moreover, when the focal distance increases to at least 75 mm, the optical coupling loss decreases by two orders of magnitude to at most 0.002 dB. When the focal distance is 150 mm, the optical coupling loss decreases down to about 0.0005 dB. This indicates that the optical coupling loss can be significantly reduced by setting the focal distance of the third lens 104 to at least 15 mm. Here, the focal distance of the third lens 104 is fixed at 15 mm based on the focal distance (0.75 mm) of the first and second lenses 102 and 103. Even if the focal distance of the first and second lenses 102 and 103 is different from 0.75 mm, similar effects are exerted provided that the ratio of the focal distances is maintained. That is, the optical coupling loss can be significantly reduced by setting the focal distance of the third lens 104 at least 20 (=15/0.75) times as long as that of the first and second lenses 102 and 103.

However, an attempt to increase the focal distance increases the radius of curvature of the lens. In particular, a focal distance of longer than 300 mm makes production of small-sized lenses difficult. Furthermore, the amount by which the third lens is adjusted (this amount corresponds to an offset distance) increases in proportion to the ratio of the focal distances; this adjustment amount is required to correct, by adjustment of position of the third lens, the displacement of the optical axis resulting from the position displacement of the first and second lenses. For example, it is assumed that the third lens 104 has a focal distance of 300 mm, whereas the first and second lenses have a focal distance of 0.75 mm and that the ratio of the focal distances of 400 (=300/0.75). Then, an offset distance required to correct 1 μm of displacement of the optical axis is 400 μm. This indicates the characteristic of the present invention that slight displacement of the third lens from the original position only insignificantly affects the optical axis and that a peripheral space required to displace the position of the third lens needs to be provided depending on the ratio of the focal distances. Hence, the increased sizes of the lenses and an excessively long offset distance both resulting from an increased focal distance prevent miniaturization of the optical semiconductor module. Thus, the focal distance of the third lens is desirably at least 20 times as long as the focal distance of the first and second lenses 102 and 103 and at most 300 mm.

### Embodiment 2

Embodiment 2 is different from Embodiment 1 in that YAG laser welding is used to fix the lenses. Compared to the use of an epoxy adhesive for fixation of the lenses, the use of YAG laser welding for fixation reduces the position displacement of the lens normally to about 1 μm. Thus, the third lens needs to correct the displacement by a reduced amount, allowing the optical axis to be easily adjusted.

Moreover, when an adhesive such as an epoxy adhesive is used, for example, the adhesive may disadvantageously be subjected to temporal changes and deformed, leading to displacement of the optical axis. However, the use of YAG laser welding serves to avoid such a problem and is thus reliable.

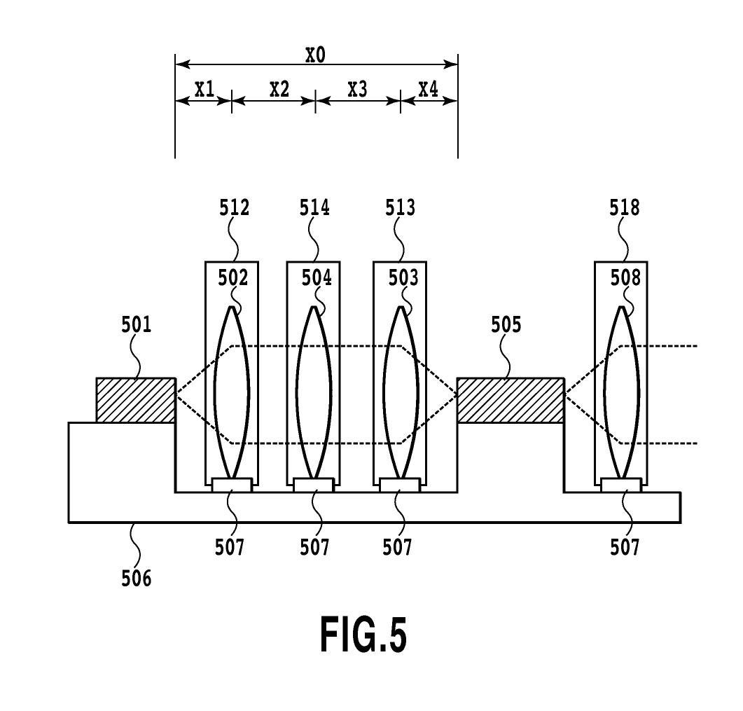

FIG. 5 shows a second embodiment of the present invention. As shown in FIG. 5, an optical semiconductor element according to the present embodiment includes, as optical semiconductor devices mounted on a carrier 506, a semiconductor laser 501 and a semiconductor optical modulator 505 both of which are waveguide-type optical semiconductor devices. The optical semiconductor module further includes a first lens 502, a second lens 503, and a third lens 504 all of which are adjusted in position such that light emitted by the semiconductor laser 501 couples to the semiconductor optical modulator 505 with a reduced optical coupling loss. The first lens 502, the second lens 503, and the third lens 504 are housed in metal housings 512, 513, and 514.

The semiconductor laser 501 used herein is a Fabry-Perot laser with a 1.55-μm oscillation wavelength band. The semiconductor optical modulator 505 used herein is a Mach-Zehnder (MZ) modulator configured to be able to deal with the 1.55-μm band.

When the optical semiconductor module according to the present embodiment is assembled, first, the two optical semiconductor devices, the semiconductor laser 501 and the semiconductor optical modulator 505, are fixed on the carrier 506. Then, the first, second, and third lenses 502, 503, and 504 are adjusted in position on the carrier 506. The first lens 502 and the second lens 503 are fixed on the carrier 506 by YAG laser welding. Finally, the third lens 504 with a long focal distance is adjusted in position again and fixed on the carrier 506 by YAG laser welding.

As described above, the third lens 504, adjusted in position again and fixed after the fixation of the first lens 502 and the second lens 503, has the long focal distance. Thus, possible displacement of the first lens 502 and the second lens 503 resulting from fixation thereof can be effectively corrected.

The following method is also possible. The initial lens position adjustment involves only the first and second lenses 502 and 503. After the first lens 502 and the second lens 503 are fixed, the third lens 504 with the long focal distance is inserted, adjusted in position, and then fixed. However, in this case, since the initial lens position adjustment does not involve the third lens 504, the displacement of the optical axis increases by an amount corresponding to the refractive index of the third lens 504. Thus, much time and effort is required to adjust in position and fix the third lens 504 after the fixation of the first and second lenses 502 and 503.

The lens 502 is arranged at a distance x1 from the exit end of the semiconductor laser 501. The lens 504 is arranged at a distance x2 from the lens 502. The lens 503 is arranged at a distance x3 from the lens 504. The incident end of the semiconductor optical modulator 505 is arranged at a distance x4 from the lens 503. Here, x1 is 0.75 mm, x2 is 5 mm, x3 is 2 mm, and x4 is 0.75 mm. Both the lenses 502 and 503 have a focal distance of 0.75 mm. The lens 504 has a focal distance of 75 mm.

The first lens 502 converts light emitted by the semiconductor laser 501 into parallel light rays. The parallel light rays pass through the third lens 504, and the second lens 503 focuses the parallel light rays on the semiconductor optical modulator 505 to couple the light rays to the semiconductor optical modulator 505. The lenses 502, 503, and 504 are adjusted in position and then fixed on the carrier 506 via a lens holder 507.

Light emitted by the semiconductor optical modulator 505 is converted into parallel light rays by a fourth lens 508. The light rays are then focused by a fifth lens (not shown in the drawings). The resultant light is connected to an optical fiber (not shown in the drawings). The fourth lens 508 is housed in a metal housing 518.

Given that the lens is displaced in position by 1 μm by YAG laser welding as shown in FIG. 2, a coupling system including only the lenses 502 and 503 suffers an optical coupling loss of about 5 dB.

On the other hand, when the lens 504 is inserted into the coupling system of the lenses 502 and 503, an optical coupling loss only of at most 0.01 dB results from the position displacement of the lens 504 as shown in FIG. 3.

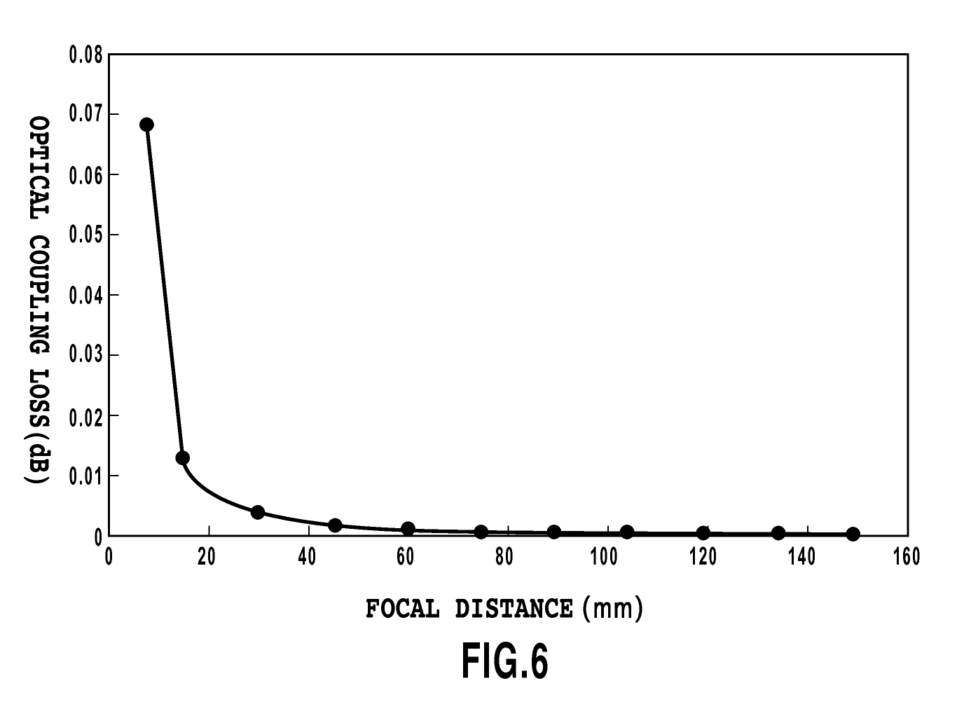

FIG. 6 illustrates the dependence of the focal distance of the lens 504 on the optical coupling loss which dependence is observed when the lenses 502 and 503 have a focal distance of 0.75 mm. The lens 504 is assumed to be displaced in position by 1 μm.

When the focal distance of the third lens 504 varies from 7.5 mm to 15 mm, the optical coupling loss decreases sharply by about one order of magnitude from about 0.07 dB to 0.01 dB. Moreover, when the focal distance increases to at least 75 mm, the optical coupling loss decreases by two orders of magnitude to at most 0.0007 dB. When the focal distance is 150 mm, the optical coupling loss decreases down to about 0.00016 dB. This indicates that the optical coupling loss can be significantly reduced by setting the focal distance of the third lens 504 to at least 15 mm. Here, the focal distance of the third lens 504 is fixed at 15 mm based on the focal distance (0.75 mm) of the first and second lenses 502 and 503. Even if the focal distance of the first and second lenses 502 and 503 is different from 0.75 mm, similar effects are exerted provided that the ratio of the focal distances is maintained. That is, the optical coupling loss can be significantly reduced by setting the focal distance of the third lens 504 at least 20 (=15/0.75) times as long as that of the first and second lenses 502 and 503.

However, an attempt to increase the focal distance increases the radius of curvature of the lens. In particular, a focal distance of longer than 300 mm makes production of small-sized lenses difficult. Furthermore, the amount by which the third lens is adjusted (this amount corresponds to an offset distance) increases in proportion to the ratio of the focal distances; this adjustment amount is required to correct, by adjustment of position of the third lens, the displacement of the optical axis resulting from the position displacement of the first and second lenses. For example, it is assumed that the third lens 504 has a focal distance of 300 mm, whereas the first and second lenses 502 and 503 have a focal distance of 0.75 mm and that the ratio of the focal distances of 400 (=300/0.75). Then, an offset distance required to correct 1 μm of displacement of the optical axis is 400 μm. This indicates the characteristic of the present invention that slight displacement of the third lens from the original position only insignificantly affects the optical axis and that a peripheral space required to displace the position of the third lens needs to be provided depending on the ratio of the focal distances. Hence, the increased sizes of the lenses and an excessively long offset distance both resulting from an increased focal distance prevent miniaturization of the optical semiconductor module. Thus, the focal distance of the third lens is desirably at least 20 times as long as the focal distance of the first and second lenses 502 and 503 and at most 300 mm.

### Embodiment 3

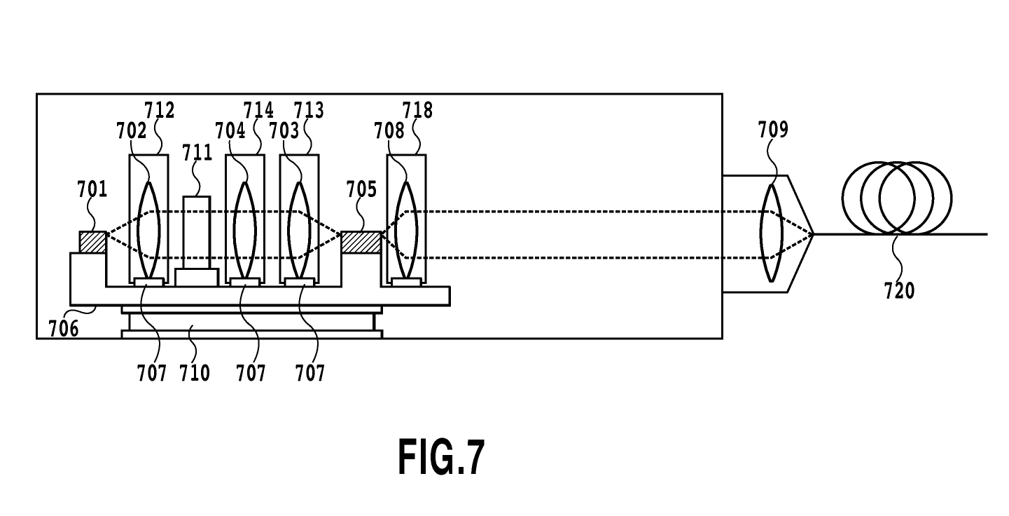

FIG. 7 shows an optical semiconductor module with an optical system similar to that of Embodiment 2 as a third embodiment of the present invention. The optical semiconductor element according to the present embodiment includes, as optical semiconductor devices mounted on a carrier 706, a semiconductor laser 701 and a semiconductor optical modulator 705 both of which are waveguide-type optical semiconductor devices. The optical semiconductor module further includes a first lens 702, a second lens 703, and a third lens 704 all of which are adjusted in position such that light emitted by the semiconductor laser 701 couples to the semiconductor optical modulator 705 with a reduced optical coupling loss. The first lens 702, the second lens 703, and the third lens 704 are housed in metal housings 712, 713, and 714, respectively.

The semiconductor laser 701 used herein is a DFB laser with a 1.55-μm oscillation wavelength band. The semiconductor optical modulator 705 used herein is a Mach-Zehnder (MZ) modulator configured to be able to deal with the 1.55-μm band.

An isolator 711 is provided between the first lens 702 and the second lens 703 to prevent reflected light from being incident on the semiconductor laser 701. The isolator 711 is arranged closer to the semiconductor laser 701 than the third lens 704. This is to prevent reflected light from the third lens 704 from being incident on the semiconductor laser 701 because the reflected light from the third lens 704 with the long focal distance seriously affects the semiconductor laser 701 when the light enters the semiconductor laser 701.

Furthermore, the optical semiconductor module according to the present embodiment includes a fourth lens 708 configured to convert light emitted by the semiconductor optical modulator 705 into parallel light rays and a fifth lens 709 configured to focus the light on an optical fiber 720. The carrier 706 is mounted on a Peltier cooler 710 for temperature control. The Peltier cooler 710 is externally controlled in temperature via electric wiring to restrain the wavelength from varying depending on temperature.

When the optical semiconductor module according to the present embodiment is assembled, first, the two optical semiconductor devices, the semiconductor laser 701 and the semiconductor optical modulator 705, are fixed on the carrier 706. Then, the first, second, and third lenses 702, 703, and 704 and the isolator 711 are adjusted in position on the carrier 706. The second lens 703, the isolator 711, and the first lens 702 are fixed on the carrier 706 in this order by YAG laser welding. Finally, the third lens 704 with a long focal distance is adjusted in position again and fixed on the carrier 706 by YAG laser welding. Thereafter, the fourth and fifth lenses 708 and 709 are fixed.

The lens 702 is arranged at a distance x1 from the exit end of the semiconductor laser 701. The isolator 711 is arranged at a distance x2 from the lens 702. The lens 704 is arranged at a distance x3 from the isolator 711. The lens 703 is arranged at a distance x4 from the lens 704. The incident end of the semiconductor optical modulator 705 is arranged at a distance x5 from the lens 703. Here, x1 is 0.75 mm, x2 is 2.5 mm, x3 is 2.5 mm, x4 is 2 mm, and x5 is 0.75 mm. Both the lenses 702 and 703 have a focal distance of 0.75 mm. The lens 704 has a focal distance of 75 mm.

The first lens 702 converts light emitted by the semiconductor laser 701 into parallel light rays. The parallel light rays pass through the third lens 704, and the second lens 703 focuses the parallel light rays on the semiconductor optical modulator 705 to couple the light rays to the semiconductor optical modulator 705. The lenses 702, 703, and 704 are adjusted in position and then fixed on the carrier 706 via a lens holder 707.

Light emitted by the semiconductor optical modulator 705 is converted into parallel light rays by the fourth lens 708. The light rays are then focused by the fifth lens 709. The resultant light is connected to the optical fiber 720. The fourth lens 708 is housed in a metal housing 718.

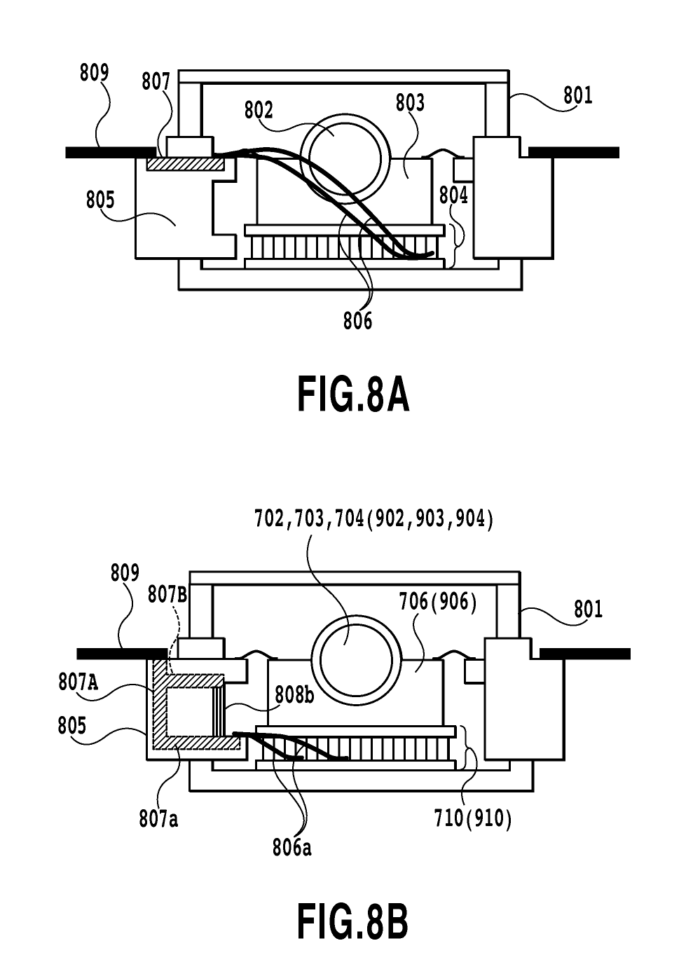

In the present embodiment, wiring for allowing a Peltier cooler 710 to be controlled is housed inside a sidewall of a package. FIG. 8A and FIG. 8B are cross-sectional views of an optical semiconductor module according to a conventional example and the optical semiconductor module according to the present embodiment, respectively.

In the conventional art, wiring for allowing a Peltier cooler to be controlled is arranged outside the sidewall of the package as shown in FIG. 8A. Specifically, metal wires 806 are used to establish connection from a Peltier cooler 804 to an inner surface of the side wall of a ceramic portion 805 of the package. The metal wires 806 are further used establish connection to an external lead frame 809 (which is exposed from the package) via a metal layer 807 arranged between partial layers in the ceramic portion 805. In this manner, wiring based on the metal wires 806 requires a space, which is a factor hindering miniaturization of the module. In FIG. 8A, reference numeral 801 denotes a package outer frame. Reference numeral 802 denotes a lens. Reference numeral 803 denotes a carrier.

In the present embodiment, as shown in FIG. 8B, the wiring for allowing the Peltier cooler 710 to be controlled is housed inside the sidewall of the package. Specifically, metal wires 806a are arranged under the carrier 706 to establish connection from the Peltier cooler 710 to the inner surface of side wall of the ceramic portion 805 and further to the external lead frame 809 (which is exposed from the package) via a metal layer 807a arranged between relevant layers in the ceramic portion 805 and a via wire 807A passed through a hole formed in the ceramic portion 805. Here, the side wall is 2.5 mm in thickness. A hole of diameter 0.2 mm is formed in the side wall at a depth of about 0.5 mm from the surface of the side wall so that the wires can be passed through the hole. At this time, connection to the external lead frame 809 is established through another path via the Peltier cooler 710, the metal wires 806a arranged under the carrier 706, a metal layer 808b with a ceramic surface, and a metal layer 807B arranged between layers in the ceramic portions 805. Electric resistance can be reduced by establishing connection to the external via wire via two paths as described above. In FIG. 8B, reference numeral 801 denotes a package outer frame, and reference numerals 702, 703, and 704 denote lenses.

As described above, the present embodiment, in which the wiring is provided inside the side wall of the package (ceramic portion), eliminates the need for a wiring space to allow the optical semiconductor module to be miniaturized, compared to the case where the wiring is arranged outside the package.

In particular, the present embodiment requires a space for the newly inserted third lens 704. Thus, housing the wiring for allowing the Peltier cooler to be controlled, inside the side wall of the package to eliminate the need for the conventional wiring space is effective for miniaturizing the optical semiconductor element. The optical semiconductor module according to the present embodiment has a package size of 30×12 mm; the present embodiment enables a reduction in conventional package size, 41×13 mm.

When the optical semiconductor module according to the present embodiment operates, output light of wavelength 1.55 μm provides CW (continuous light) power+6.5 dBm, which is greater than a value provided by the conventional structure. When the optical semiconductor module according to the present embodiment is used to perform 200-km duo binary transmission at 10 Gb/s with an extinction voltage for modulation by the semiconductor modulator set to 2.1 V, power penalty is 1 dB. That is, a favorable result is obtained.

In the present embodiment, no element is arranged between the lens 708 and the lens 709. However, if a wavelength locker is arranged between the lens 708 and the lens 709, the optical output and wavelength can be controlled. Furthermore, the optical output can be controlled by arranging a photodiode (power monitor) between the lens 708 and the lens 709 via a translucent mirror.

### Embodiment 4

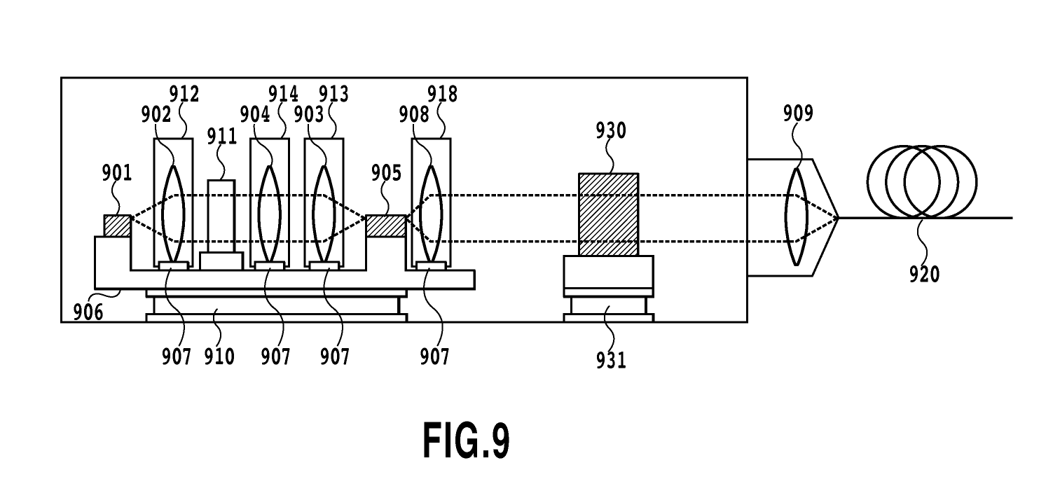

FIG. 9 shows, as Embodiment 4, a case in which a wavelength tunable light source is used as a light source (semiconductor laser) for an optical semiconductor module according to Embodiment 3.

The optical semiconductor module according to the present embodiment includes, as optical semiconductor devices mounted on a carrier 906, a TLA (Tunable Laser Array) 901 and a semiconductor optical modulator 905 both of which are wavelength tunable light sources. The optical semiconductor module further includes a first lens 902, a second lens 903, and a third lens 904 all of which are adjusted in position such that light emitted by the TLA 901 couples to the semiconductor optical modulator 905 with a reduced optical coupling loss. The first lens 902, the second lens 903, and the third lens 904 are housed in metal housings 912, 913, and 914.

The TLA 901 is an array of 12 DFB laser devices arranged in parallel. The TLA 901 deals with the C band (1.530 μm to 1.560 μm) with 97 channels at a channel spacing of 50 GHz. Furthermore, the semiconductor optical modulator 905 used herein is a Mach-Zehnder (MZ) modulator configured to be able to deal with the 1.55 μm band.

An isolator 911 is provided between the first lens 902 and the second lens 903 to prevent reflected light from being incident on the TLA 901. The isolator 911 is arranged closer to the TLA 901 than the third lens 904. This is to prevent reflected light from the third lens 904 from being incident on the TLA 901 because the reflected light from the third lens 904 with the long focal distance seriously affects the TLA 901 when the light enters the TLA 901.

Furthermore, the optical semiconductor module according to the present embodiment includes a fourth lens 908 configured to convert light emitted by the semiconductor optical modulator 905 into parallel light rays and a fifth lens 909 configured to focus the light on an optical fiber 920. The carrier 906 is mounted on a Peltier cooler 910 for temperature control. The Peltier cooler is externally controlled in temperature via electric wiring. The Peltier cooler is used to vary the temperature of the TLA 901 and thus the oscillation wavelength of the TLA 901.

In addition, the optical semiconductor module includes a wavelength locker 930 in order to control light with a plurality of wavelengths. The wavelength locker 930 is mounted on a Peltier cooler 931 so as to lie between the lens 908 and the lens 909. In the wavelength locker 930, part of incident light (light output by the semiconductor optical modulator 905) is reflected by a translucent mirror so as to enter a photodiode (power monitor) PD1 (not shown in the drawings). Furthermore, another part of the incident light is allowed to enter a photodiode PD2 (not shown in the drawings) via a wavelength filter. The part of the light which has failed to be reflected by the translucent mirror is focused on the optical fiber 920 by the lens 909 as transmitted light.

Light received by each of the photodiodes PD1 and PD2 is converted into electricity, which is then input to a control device located outside the optical semiconductor module. The control device controls a current (operating current) input to the TLA 901 in accordance with the input currents from the photodiodes PD1 and PD2, thus stabilizing an optical output of each wavelength. Furthermore, the control device controls a current input to the Peltier cooler 910 to vary the oscillation wavelength of the TLA 901. Additionally, another control device is used to apply a voltage to the semiconductor optical modulator 905 to operate the semiconductor optical modulator 905.

When the optical semiconductor module according to the present embodiment is assembled, first, the two optical semiconductor devices, the TLA 901 and the semiconductor optical modulator 905, are fixed on the carrier 906. Then, the first, second, and third lenses 902, 903, and 904 and the isolator 911 are adjusted in position on the carrier 906. The second lens 903, the isolator 911, and the first lens 902 are fixed on the carrier 906 in this order by YAG laser welding. Finally, the third lens 904 with a long focal distance is adjusted in position again and fixed on the carrier 906 by YAG laser welding. Thereafter, the fourth and fifth lenses 908 and 909 are fixed.

The lens 902 is arranged at a distance x1 from the exit end of the TLA 901. The isolator 911 is arranged at a distance x2 from the lens 902. The lens 904 is arranged at a distance x3 from the isolator 911. The lens 903 is arranged at a distance x4 from the lens 904. The incident end of the semiconductor optical modulator 905 is arranged at a distance x5 from the lens 903. Here, x1 is 0.75 mm, x2 is 2.5 mm, x3 is 2.5 mm, x4 is 2 mm, and x5 is 0.75 mm. Both the lenses 902 and 903 have a focal distance of 0.75 mm. The lens 904 has a focal distance of 75 mm.

The first lens 902 converts light emitted by the TLA 901 into parallel light rays. The parallel light rays pass through the third lens 904, and the second lens 903 then focuses the parallel light rays on the semiconductor optical module 905 to couple the light rays to the semiconductor optical modulator 905. The lenses 902, 903, and 904 are adjusted in position and then fixed on the carrier 906 via a lens holder 907.

Light emitted by the semiconductor optical modulator 905 is converted into parallel light rays by the fourth lens 908. The light rays are then focused by the fifth lens 909 via a wavelength locker 930. The resultant light is connected to the optical fiber 920. The fourth lens 908 is housed in a metal housing 918.

In the present embodiment, wiring for allowing a Peltier cooler to be controlled is housed inside a sidewall of a package. FIG. 8A and FIG. 8B are cross-sectional views of the optical semiconductor module according to the conventional example and the optical semiconductor module according to the present embodiment, respectively.

In the conventional art, wiring for allowing a Peltier cooler to be controlled is arranged outside the sidewall of the package as shown in FIG. 8A. Specifically, the metal wires 806 are used to establish connection from the Peltier cooler 804 to the inner surface of the side wall of the ceramic portion 805 of the package. The metal wires 806 are further used establish connection to the external lead frame 809 via the metal layer 807 arranged between partial layers in the ceramic portion 805. In this manner, the wiring based on the metal wires 806 requires a space, which is a factor hindering miniaturization of the module.

In the present embodiment, as shown in FIG. 8B, the wiring for allowing the Peltier cooler 910 to be controlled is housed inside the sidewall of the package. Specifically, the metal wires 806a are arranged under the carrier 906 to establish connection from the Peltier cooler 910 to the inner surface of side wall of the ceramic portion 805 and further to the external lead frame 809 via the via wire 807A passed through the hole formed in the ceramic portion 805. Here, the side wall is 2.5 mm in thickness. A hole of diameter 0.2 mm is formed in the side wall at a depth of about 0.5 mm from the surface of the side wall so that the wires can be passed through the hole. At this time, connection to the external lead frame 809 is established through another path via the Peltier cooler 910, the metal wires 806a arranged under the carrier 906, the metal layer 808b with the ceramic surface, and the metal layer 807B arranged between the relevant layers in the ceramic portions 805. Electric resistance can be reduced by establishing connection to the external via wire via two paths as described above. In FIG. 8B, reference numeral 801 denotes a package outer frame, and reference numerals 902, 903, and 904 denote lenses.

As described above, the present embodiment, in which the wiring is provided inside the side wall of the package (ceramic portion), eliminates the need for a wiring space to allow the optical semiconductor module to be miniaturized, compared to the case where the wiring is arranged outside the package.

In particular, the present embodiment requires a space for the newly inserted third lens 904. Thus, housing the wiring for allowing the Peltier cooler to be controlled, inside the side wall of the package to eliminate the need for the conventional wiring space is effective for miniaturizing the optical semiconductor element.

The optical semiconductor module according to the present embodiment has a package size of 30×12 mm; the present embodiment enables a reduction in conventional package size, 41×13 mm.

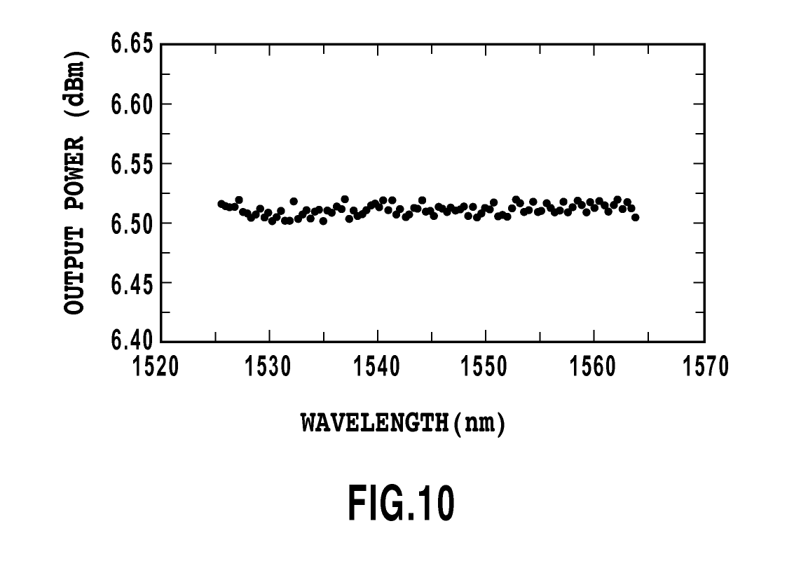

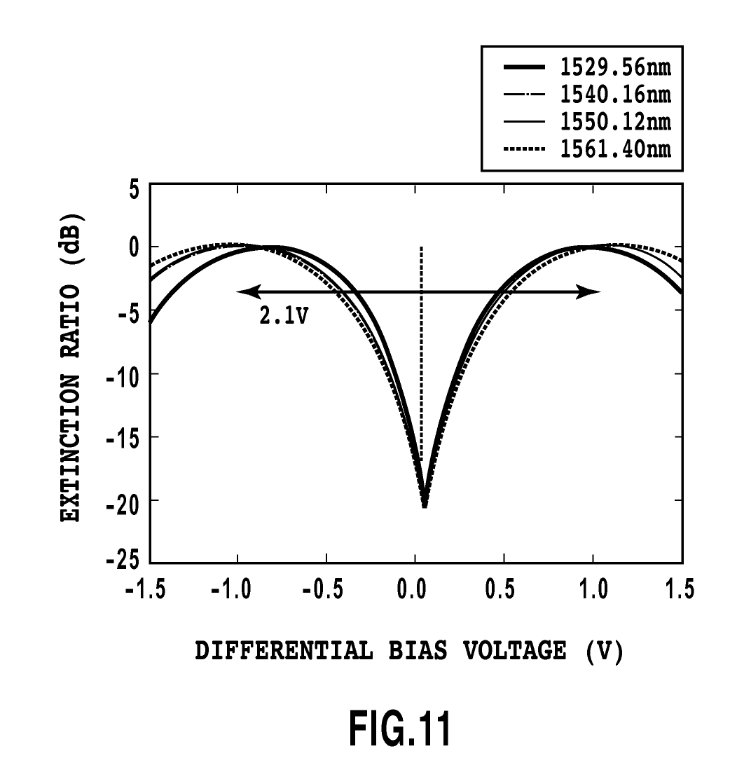

FIG. 10 illustrates an output from the optical fiber in the optical semiconductor module according to the present embodiment. The optical semiconductor module according to the present embodiment provides CW power+6.5 dBm at all the wavelengths in the C band (1.530 μm to 1.560 μm) with 97 channels at a channel spacing of 50 GHz. FIG. 11 illustrates the extinction characteristic of the optical modulator 905. A π voltage (Vπ) is 2.1 V over the range of all the wavelengths in the C band, indicating that the optical semiconductor module operates at a low voltage.

The results of 10-Gbit/s duo binary transmission through 200 km of single mode fibers (SMFs) using the optical semiconductor module according to the present embodiment will be illustrated. Here, the optical modulator 905 was allowed to perform a push-pull operation. A driving voltage was kept constant (2.1 Vpp/2.4 Vpp). Only a bias voltage was varied between −5.4 V and −11.0 V depending on the laser oscillation wavelength and the temperature.

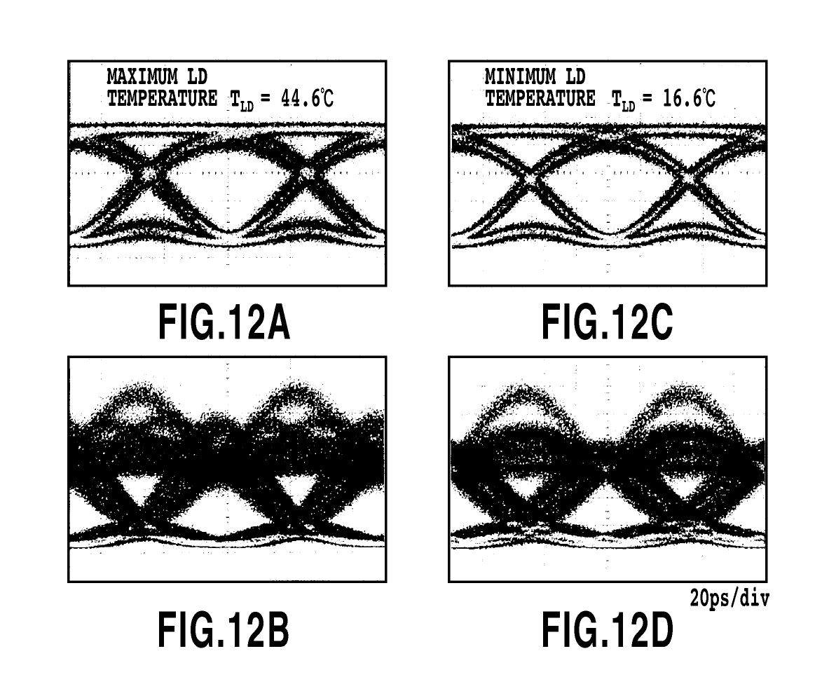

FIG. 12A shows an eye pattern observed before transmission when the wavelength is 1529.55 nm. FIG. 12B shows an eye pattern observed after transmission when the wavelength is 1529.55 nm. FIG. 12C shows an eye pattern observed before transmission when the wavelength is 1561.42 nm. FIG. 12D shows an eye pattern observed after transmission when the wavelength is 1561.42 nm. At wavelengths of 1529.55 nm and 1561.42 nm, appropriate eyes were obtained before and after transmission.

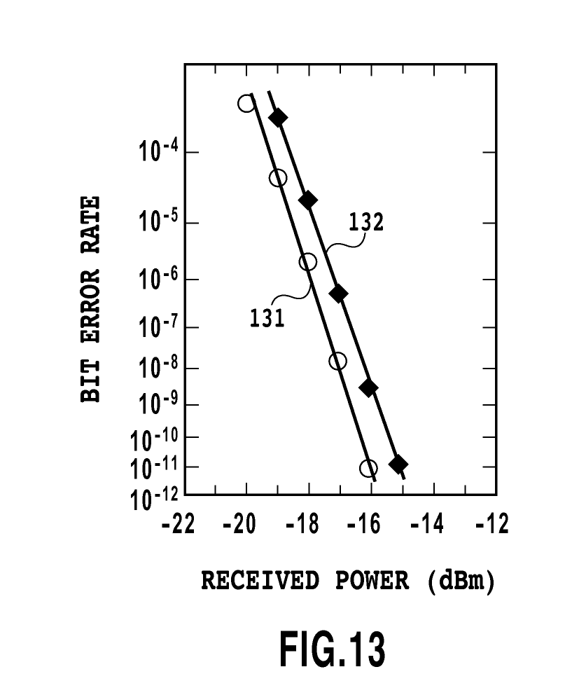

FIG. 13 illustrates a code error characteristic (before transmission: 131; after transmission: 132). All over the C band, power penalty is at most 1.0 dBm before and after transmission with 200 km of SMFs. Thus, the present embodiment enables the following to be achieved all over the C band: a CW optical output of +6.5 dBm, a 10 Gb/s operation in all the wavelength bands under non-adjusted modulator driving conditions, and duo binary transmission with 200 km of SMFs.

In the present embodiment, the first lens 902 and the second lens 903 have the equal focal distance. However, the first lens 902 and the second lens 903 may have different focal distances. In this case, the third lens 904 may have a focal distance longer than the longer one of the focal distances of the first and second lenses 902 and 903. In the present embodiment, the first lens 902 and the second lens 903 have a focal distance of 0.75 mm, and the third lens 904 has a focal distance of 75 mm. However, the lenses may have other focal distances provided that the third lens 904 has a longer focal distance than the first lens 902 and the second lens 903.

In the present embodiment, the TLA 901 is used as a tunable wavelength light source. However, a DBR laser may be used. Furthermore, in the present embodiment, the semiconductor optical modulator 905 is used as a modulator. However, an LN modulator may be used. Additionally, in the present embodiment, the wavelength locker 930 and the carrier 906 with the TLA 901 and the semiconductor optical modulator 905 mounted thereon are mounted on the separate Peltier coolers 931 and 910, respectively. However, the wavelength locker 931 and the carrier 906 may be mounted on the same Peltier cooler.

The present embodiment is configured to deal with the C band (1.530 μm to 1.560 μm). However, the present embodiment may be configured to apply to the L band (1.580 μm to 1.620 μm). In the present embodiment, the optical semiconductor module deals with the 1.55-μm wavelength band. However, the optical semiconductor module may be applied to a 1.3-μm band by using a semiconductor laser and a modulator both configured to deal with the 1.3-μm band.

### REFERENCE SIGNS LIST

101, 501, 701 Semiconductor lasers
102, 502, 702, 902 First lenses
103, 503, 703, 903 Second lenses
104, 504, 704, 904 Third lenses
105, 505, 705, 905 Semiconductor optical modulators
106, 506, 706, 803, 906 Carriers
507, 707, 907 Lens holders
108, 508, 708, 908 Fourth lenses
709, 909 Fifth lenses
710, 804, 910, 931 Peltier coolers
711, 911 Isolators
512, 513, 514, 518, 712, 713, 714, 718, 912, 913, 914, 918 Metal housings
720, 920 Optical fibers
801 Package outer frame
802 Lens
805 Ceramic portion
806 Metal wires
807, 807a, 807B Metal layers each arranged between relevant layers in ceramic portion 805
807A Via wire
808b Metal layer with ceramic layer
809 External lead frame
901 TLA
930 Wavelength locker

1. An optical semiconductor module comprising a first optical element, a first lens configured to convert light emitted by the first optical element into parallel light rays, a second lens configured to focus the parallel light rays, a third lens arranged between the first lens and the second lens, and a second optical element positioned such that the light is focused on the second optical element by the second lens, the first optical element, the first lens, the second lens, the third lens, and the second optical element being built into the optical semiconductor module, the optical semiconductor module being characterized in that:
the third lens has a longer focal length than each of the first lens and the second lens.

2. The optical semiconductor module according to claim 1, characterized in that,
when the first lens and the second lens have an equal focal distance, the focal distance of the third lens is at least 20 times as long as the focal distance of the first and second lenses and at most 300 mm, and
when the first lens and the second lens have different focal distances, the focal distance of the third lens is at least 20 times as long as a longer one of the focal distances of the first and second lenses and at most 300 mm.

3. The optical semiconductor module according to claim 1, characterized in that,
the first lens, the second lens, and the third lens are housed in a metal housing, and
the first lens, the second lens, and the third lens are fixed, by YAG laser welding, on a carrier with the first optical semiconductor element and the second optical semiconductor element mounted thereon.

4. The optical semiconductor module according to claim 6, characterized in that an isolator is provided between the first lens and the third lens.

5. The optical semiconductor module according to claim 2, characterized in that,
the first optical element is a light source, and
the second optical element is an optical modulator.

6. The optical semiconductor module according to claim 5, characterized in that,
the first optical element is a wavelength tunable laser, and
the optical semiconductor module comprises a wavelength locker at a position on which light output by the second optical element is incident.

7. A method for assembling an optical semiconductor module according to claim 3, the method being characterized by comprising:
fixing a first optical element and a second optical element on a carrier;
then adjusting a first lens, a second lens, and a third lens in position so that light focused by the second lens couples to the second optical element; and
fixing the first lens and the second lens to the carrier by YAG laser welding and then fixing the third lens with a long focal distance to the carrier.

8. The optical semiconductor module according to claim 1, comprising the first optical element and the second optical element, a carrier with the first optical element, the second optical element, the first lens, the second lens, and the third lens mounted thereon, and a Peltier cooler with the carrier mounted thereon, the optical element, the carrier, and the Peltier cooler being all provided in a package, as well as a lead frame exposed from the package in order allow an electric signal to be input and output, the optical semiconductor module being characterized in that,
a part of a side wall of the package is ceramic,
electric wiring for allowing the Peltier cooler to be controlled is arranged under the carrier, and
the electric wiring is further arranged through a hole inside the ceramic so as to connect to the lead frame.

9. The optical semiconductor module according to claim 8, characterized in that the electric wiring for allowing the Peltier cooler to be controlled is connected to a metal layer arranged in a part of an inner wall surface of the ceramic, and the electric wiring is further arranged though an inside of the ceramic so as to connect to the lead frame.

10. The optical semiconductor module according to claim 2, comprising the first optical element and the second optical element, a carrier with the first optical element, the second optical element, the first lens, the second lens, and the third lens mounted thereon, and a Peltier cooler with the carrier mounted thereon, the optical element, the carrier, and the Peltier cooler being all provided in a package, as well as a lead frame exposed from the package in order allow an electric signal to be input and output, the optical semiconductor module being characterized in that,
a part of a side wall of the package is ceramic,
electric wiring for allowing the Peltier cooler to be controlled is arranged under the carrier, and
the electric wiring is further arranged through a hole inside the ceramic so as to connect to the lead frame.

11. The optical semiconductor module according to claim 3, comprising the first optical element and the second optical element, a carrier with the first optical element, the second optical element, the first lens, the second lens, and the third lens mounted thereon, and a Peltier cooler with the carrier mounted thereon, the optical element, the carrier, and the Peltier cooler being all provided in a package, as well as a lead frame exposed from the package in order allow an electric signal to be input and output, the optical semiconductor module being characterized in that,
a part of a side wall of the package is ceramic,
electric wiring for allowing the Peltier cooler to be controlled is arranged under the carrier, and
the electric wiring is further arranged through a hole inside the ceramic so as to connect to the lead frame.

12. The optical semiconductor module according to claim 4, comprising the first optical element and the second optical element, a carrier with the first optical element, the second optical element, the first lens, the second lens, and the third lens mounted thereon, and a Peltier cooler with the carrier mounted thereon, the optical element, the carrier, and the Peltier cooler being all provided in a package, as well as a lead frame exposed from the package in order allow an electric signal to be input and output, the optical semiconductor module being characterized in that,
a part of a side wall of the package is ceramic,
electric wiring for allowing the Peltier cooler to be controlled is arranged under the carrier, and
the electric wiring is further arranged through a hole inside the ceramic so as to connect to the lead frame.

13. The optical semiconductor module according to claim 5, comprising the first optical element and the second optical element, a carrier with the first optical element, the second optical element, the first lens, the second lens, and the third lens mounted thereon, and a Peltier cooler with the carrier mounted thereon, the optical element, the carrier, and the Peltier cooler being all provided in a package, as well as a lead frame exposed from the package in order allow an electric signal to be input and output, the optical semiconductor module being characterized in that,
a part of a side wall of the package is ceramic,
electric wiring for allowing the Peltier cooler to be controlled is arranged under the carrier, and
the electric wiring is further arranged through a hole inside the ceramic so as to connect to the lead frame.

14. The optical semiconductor module according to claim 6, comprising the first optical element and the second optical element, a carrier with the first optical element, the second optical element, the first lens, the second lens, and the third lens mounted thereon, and a Peltier cooler with the carrier mounted thereon, the optical element, the carrier, and the Peltier cooler being all provided in a package, as well as a lead frame exposed from the package in order allow an electric signal to be input and output, the optical semiconductor module being characterized in that,
a part of a side wall of the package is ceramic,
electric wiring for allowing the Peltier cooler to be controlled is arranged under the carrier, and
the electric wiring is further arranged through a hole inside the ceramic so as to connect to the lead frame.
